(19) United States
(12) Patent Application Publication
(10) Pub. No.: US 2021/0189165 A1
(43) Pub. Date: Jun. 24, 2021

(54) PRINTABLE AMMONIUM-BASED CHALCOGENOMETALATE FLUIDS

(71) Applicant: Hewlett-Packard Development Company, L.P., Spring, TX (US)

(72) Inventors: Robert Ionescu, Palo Alto, CA (US); Ning Ge, Palo Alto, CA (US); Helen A. Holder, Palo Alto, CA (US); Jarrid Wittkopf, Palo Alto, CA (US)

(73) Assignee: Hewlett-Packard Development Company, L.P., Spring, TX (US)

(21) Appl. No.: 16/756,862

(22) PCT Filed: Oct. 19, 2017
(86) PCT No.: PCT/US2017/057321

§ 371 Date: Apr. 17, 2020

(51) Int. Cl. C09D 11/52; C09D 11/38; B41J 2/14; B41M 7/00

(52) U.S. Cl. CPC C09D 11/52; B41M 7/009; B41J 2/14088; C09D 11/38

(57) ABSTRACT

In one example in accordance with the present disclosure, a printable ammonium-based chalcogenometalate fluid is described. The fluid includes an ammonium-based chalcogenometalate precursor. The printable ammonium-based chalcogenometalate fluid also includes an aqueous solvent and water. The printable ammonium-based chalcogenometalate fluid is printed onto a substrate. In the presence of heat, the aqueous solvent, water, and ammonium-based chalcogenometalate precursor break down to form a transition metal dichalcogenide having the form MX₂.

### BACKGROUND

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a natural semiconductor with a thickness on the atomic scale.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a printable ammonium-based chalcogenometalate fluid, according to an example of the principles described herein.

FIG. 2 is a flowchart of a method for printing an ammonium-based chalcogenometalate fluid, according to an example of the principles described herein.

FIG. 3 is a diagram of a printing system for printing an ammonium-based chalcogenometalate fluid, according to an example of the principles described herein.

FIG. 4 is a flowchart of a method for printing an ammonium-based chalcogenometalate fluid, according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

A semiconductor refers to any material that has an electrical conductivity between a conductor and an insulator. Such semiconductors are used in various applications including field effect transistors (FETs), optoelectronics, photodetectors, phototransistors, photosensors, photovoltaic cells and light-emitting diodes (LEDs). A two-dimensional (2D) semiconductor is a natural semiconductor with a thickness on the atomic scale. 2D semiconductors are a promising component for advancing next generation electronics.

One such material that is used in these 2D semiconductors is a transition metal dichalcogenide (TMD) which is a combination of a transition metal and a chalcogen and has the form MX₂. As described above, such 2D semiconductors offer great potential in improving electronic device functionality. For example, poor energy efficiency in optoelectronics can be greatly improved using 2D semiconductive materials that have direct bandgap in the visible light. Unlike the indirect bandgap of silicon, a 2D layered semiconductor has a direct bandgap single-layer. This direct bandgap is effective and relevant in light emission applications and for use with other light-based devices. In another example, transistors formed using 2D layered semiconductors provide high electron mobility, provide a high on/off ratio, and facilitate transparent ultra-thin devices.

While semiconductors, and 2D semiconductors in particular, have undoubtedly advanced electrical and electronic developments in general and will inevitably continue to do so, some characteristics impede their more complete implementation. For example, manufacturing these 2D semiconductors can rely on a chemical vapor deposition (CVD) system that uses powder precursors, specifically oxides such as molybdenum trioxide (MoO₃) and tungsten trioxide (WO₃). These oxides result in non-uniform growth of the semiconductive material, which non-uniform growth reduces the certainty of semiconductor shape and size, thus reducing their practical implementation. Moreover, CVD processes are based on nucleation, which can include numerous heating cycles which are dirty and time consuming, for example between 2-3 hours. In some cases, such as for the manufacturing of field effect transistors, the manufacturing is performed in a clean room, which in and of itself is complex and costly. For example, CVD processes can implement a quartz tube which has to be cleaned and maintained after the CVD operation. These complications are exacerbated if a heterogeneous structural stack of these semiconductors are formed, which can include multiple CVD operations.

Accordingly, the present specification describes a printable ammonium-based chalcogenometalate fluid which is processed to form an atomically thin layer of 2D semiconductive material. Specifically, the present specification describes an ammonium-based chalcogenometalate ink, or a printable ammonium-based chalcogenometalate fluid, that can provide efficient processing methods. That is, a fluid is described that can be printed onto any substrate, and heated to form a solid 2D semiconductive component. Vertically heterogeneous structural stacks of these components can exhibit increased photon absorption which, along with direct band gap properties, have opened new roads in optoelectronics. Moreover, rather than using multiple iterations of a CVD process, the present printable fluid can be printed layer-by-layer without any further transferring or processing. Full semiconductive devices can be directly printed without any cleanroom. Moreover, due to the precise manner in which the ink, or printable fluid, can be deposited, there are no etching or patterning of the material.

Specifically, the present specification describes a printable ammonium-based chalcogenometalate fluid. The fluid includes an ammonium-based chalcogenometalate precursor. The fluid also includes an aqueous solvent and water. The printable ammonium-based chalcogenometalate fluid is printed onto a substrate. In the presence of heat, the aqueous solvent, water, and ammonium-based chalcogenometalate precursor dissipate to form a transition metal dichalcogenide (TMD) having the form MX₂.

The present specification also describes a method for printing the transition metal dichalcogenide (TMD). In the method, an ammonium-based chalcogenometalate precursor is combined with an aqueous solvent and water to form a first printable ammonium-based chalcogenometalate fluid. The first printable ammonium-based chalcogenometalate fluid is ejected from a nozzle of a printing system onto a substrate to form a layer of the first printable ammonium-based chalcogenometalate fluid. The layer is heated to dissipate the first printable ammonium-based chalcogenometalate fluid into a solid transition metal dichalcogenide (TMD) having the form MX₂.

The present specification also describes a printing system. The printing system includes a number of nozzles to eject an amount of printable ammonium-based chalcogenometalate fluid. Each nozzle includes 1) a firing chamber to hold the amount of printable ammonium-based chalcogenometalate fluid, 2) an opening, and 3) an ejector to eject the amount of printable ammonium-based chalcogenometalate fluid through the opening. The printing system also includes a reservoir to supply the printable ammonium-based chalcogenometalate fluid to the number of nozzles. The printable ammonium-based chalcogenometalate fluid includes 1) an ammonium-based chalcogenometalate precursor having the form (NH₄)₂MX₄, where M is a transition metal and X is a chalcogen, 2) an aqueous solvent, and 3) water. In the presence of heat, the printable ammonium-based chalcogenometalate fluid dissipates to form a transition metal dichalcogenide (TMD) having the form MX₂.

In summary, using such a fluid and method 1) provides manufacturing of 2D semiconductive materials that is cheaper, technically advanced, and more expeditious; 2) expands 2D semiconductor implementation to additional industries not previously available; 3) allows for fabrication of 2D semiconductive materials on substrates that previously were not feasible; 4) provides innumerable options regarding shapes of semiconductive structures; and 5) provides for fully-printable devices such as FETs. However, it is contemplated that the devices disclosed herein may address other matters and deficiencies in a number of technical areas.

As used in the present specification and in the appended claims, the term “a number of” or similar language is meant to be understood broadly as any positive number including 1 to infinity.

Moreover, as used in the present specification and in the appended claims, the term chalcogenometalate, may refer to transition metal thiometalates, or transitional metal-chalcogen compounds.

In the following description, for purposes of explanation, numerous specific details are set forth in order to provide a thorough understanding of the present systems and methods. It will be apparent, however, to one skilled in the art that the present apparatus, systems, and methods may be practiced without these specific details. Reference in the specification to “an example” or similar language means that a particular feature, structure, or characteristic described in connection with that example is included as described, but may or may not be included in other examples.

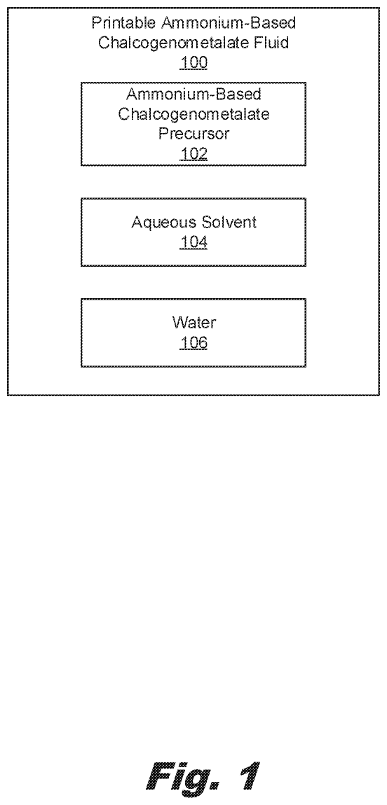

FIG. 1 is a block diagram of a printable ammonium-based chalcogenometalate fluid (100), according to an example of the principles described herein. In some examples, the printable ammonium-based chalcogenometalate fluid (100) is an ink. As with ink, the printable ammonium-based chalcogenometalate fluid (100) is deposited on a substrate in a particular pattern. That is, the printable ammonium-based chalcogenometalate fluid (100) is printable in any shape, such as a logo, to form a semiconductor on a substrate in the same shape, i.e., the logo. After deposition, the printable ammonium-based chalcogenometalate fluid (100) is treated such that a transition metal dichalcogenide (TMD) is left. The transition metal dichalcogenide is a 2D semiconductive material that is one atomic layer thick. As described above and will be described in more detail below, the ammonium-based chalcogenometalate fluid (100) is printable and can be given any shape and works on various substrates.

The printable ammonium-based chalcogenometalate fluid (100) includes an ammonium-based chalcogenometalate precursor (102) that serves as the base of the fluid. The ammonium-based chalcogenometalate precursor (102) may have the form (NH₄)₂MX₄. In this example, M, is a transition metal as indicated on the periodic table. Specific examples of transition metals include molybdenum and tungsten, however, other transition metals may be implemented as well. The X is a chalcogen atom as indicated on the periodic table. Examples of chalcogens include oxygen, sulfur, selenium, and tellurium. Specific examples of ammonium-based chalcogenometalate precursors (102) having the form (NH₄)₂MX₄ that may be found in the printable ammonium-based transition metal fluid (100) include ammonium tetrathiotungstate, (NH₄)₂WS₄, and ammonium tetrathiomolybdate, (NH₄)₂MoS₄.

While specific reference is made to particular ammonium-based chalcogenometalate precursors (102), a variety of ammonium-based chalcogenometalate precursors (102) may be used. This ammonium-based chalcogenometalate precursor (102) can be developed into a printable ammonium-based chalcogenometalate fluid (100), or an ammonium-based chalcogenometalate ink, and printed directly on substrates such as a metallic substrate. In another example, the substrate may be a graphene substrate which has properties desirable in electrical or electronic applications.

The printable ammonium-based chalcogenometalate fluid (100) also includes an aqueous solvent (104). The aqueous solvent (104) dissolves the ammonium-based chalcogenometalate precursor (102) which comes in a powder form. The aqueous solvent (104) may be any type of solvent including dimethyl sulfoxide (DMSO); dimethylformamide (DMF); N-methyl-20prrolidone (NMP); and 1,2-Hexanediol, among other -diol based solvents. While specific reference is made to particular aqueous solvents (104), a variety of aqueous solvents (104) may be used, which solvents may be selected based on the ammonium-based chalcogenometalate precursor (102) that is used.

The printable ammonium-based chalcogenometalate fluid (100) also includes water (106). The aqueous solvent (104) and water (106) may be mixed in any variety of ratios to achieve a desired printable concentration. For example, the aqueous solvent (104) and water (106) may be found in a ratio of 2 to 3. However, any desired mixture ratio may be used to achieve different properties, such as different viscosities.

In some examples, the various components of the printable ammonium-based chalcogenometalate fluid (100), i.e., the ammonium-based chalcogenometalate precursor (102), the aqueous solvent (104), and the water (106), as well as the amounts and ratios of each component, may be selected based on the substrate onto which the printable ammonium-based chalcogenometalate fluid (100) is to be printed. In other words, the printable ammonium-based chalcogenometalate fluid (100) can easily be printed on numerous substrates. Examples of substrates that can be printed on include graphene, glass, polyethylene terephthalate, aluminum, quartz, sapphire, silicon, silicon dioxide, copper, nickel, ceramics, and gold. As mentioned above, the specific composition and mixture of the printable ammonium-based chalcogenometalate fluid (100) may be dependent upon the particular substrate selected.

Following printing, the printable ammonium-based chalcogenometalate fluid (100) is subject to a heating operation, wherein the aqueous solvent (104), water (106), and ammonium-based chalcogenometalate precursor (102) dissipate to form a transition metal dichalcogenide (TMD) having the form MX₂. For example, when the ammonium-based chalcogenometalate precursor (102) is ammonium tetrathiotungstate, (NH₄)₂WS₄, the resulting transition metal dichalcogenide is tungsten disulfide, WS₂, and when the ammonium-based chalcogenometalate precursor (102) is ammonium tetrathiomolybdate, (NH₄)₂MoS₄, the resulting transition metal dichalcogenide is molybdenum disulfide MoS₂. In some cases, the resulting transition metal dichalcogenide is transparent, such that a pattern or image on a substrate and underneath the TMD is visible. For example, a colored logo may be placed on the substrate and the printable ammonium-based chalcogenometalate fluid (100) disposed thereon such that it appears as if the logo itself is the semiconductive component.

Thus, using the printable ammonium-based chalcogenometalate fluid (100) described herein, any design or shape of ammonium-based chalcogenometalate fluid (100) can be printed with high accuracy, resulting in a TMD semiconductive element of the same design or shape. Moreover, the process is simple and does not implement specialized machinery. For example, the fluid (100) could be loaded into a printer cartridge such as an inkjet cartridge and printed with an inkjet printer.

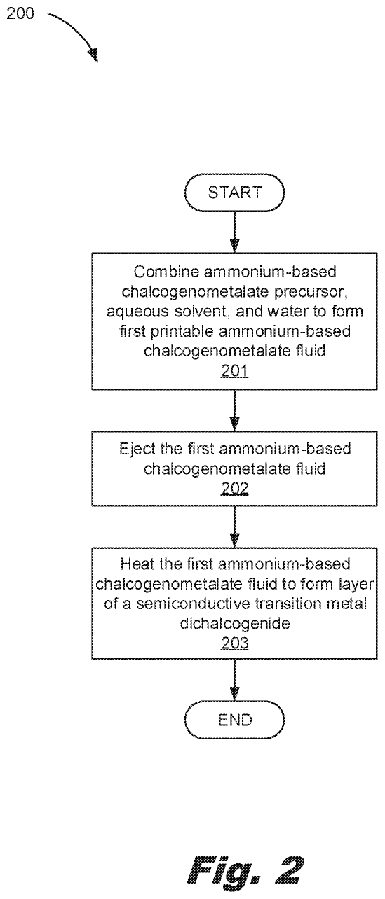

FIG. 2 is a flowchart of a method (200) for printing an ammonium-based chalcogenometalate fluid (FIG. 1, 100), according to an example of the principles described herein. According to the method (200), an ammonium-based chalcogenometalate precursor (FIG. 1, 102), aqueous solvent (FIG. 1, 104), and water (FIG. 1, 106) are combined (block 201) to form a first printable ammonium-based chalcogenometalate fluid (FIG. 1, 100). The different components may be mixed in any amounts, and any ratio, based on any number of factors, such as desired viscosity, printer characteristics, printer cartridge characteristics, and the substrate on which the printable ammonium-based chalcogenometalate fluid (FIG. 100) is to be deposited.

The first printable ammonium-based chalcogenometalate fluid (FIG. 1, 100) is then ejected (block 202) onto a surface. For example, the first printable ammonium-based chalcogenometalate fluid (FIG. 1, 100) may be placed in a printing system that has a nozzle to eject fluid therefrom. The nozzle could be activated to eject the first printable ammonium-based chalcogenometalate fluid (FIG. 1, 100) onto a substrate. The ejection (block 202) may be done in any number of patterns, such as electrical leads, logos, or other shapes.

Once ejected, the first printable ammonium-based chalcogenometalate fluid (FIG. 1, 100) is heated (block 203). Doing so causes the printable ammonium-based chalcogenometalate fluid (FIG. 1, 100) to break down to form a transition metal dichalcogenide, which is a semiconductive component. More specifically, after printing, the substrate with the printable ammonium-based chalcogenometalate fluid (FIG. 1, 100) disposed thereon is heated to a temperature of 900 degrees Celsius for 10 minutes under nitrogen flow. In a specific example, where the ammonium-based transition met chalcogenometalate al fluid (FIG. 1, 100) is ammonium tetrathiomolybdate, (NH₄)₂MS₄, once heated above 200 degrees Celsius, the printable ammonium-based chalcogenometalate fluid (FIG. 1, 100) breaks down into a combination of molybdenum trisulfide, MoS₃, two molecules of ammonia 2(NH₃) and hydrogen sulfide, H₂S. Once the temperature is above 500 degrees Celsius up to 900 degrees Celsius, the molybdenum trisulfide further decomposes into molybdenum disulfide, MoS₂, and sulfur, S, and becomes crystalline, which molybdenum disulfide is a 2D semiconductive material. In this fashion, a 2D semiconductive material having the form MX₂, is printed on a substrate. Printing this fluid (FIG. 1, 100) provides greater flexibility and simplicity in forming 2D semiconductive materials and expands the use of such materials more fully into some technical areas and introduces it into use in other technical areas.

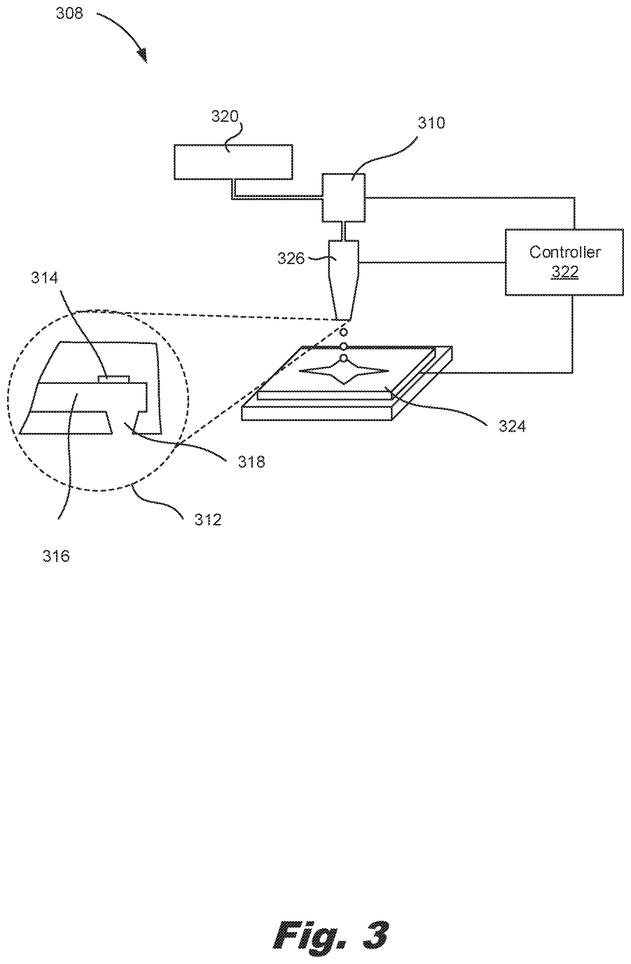

FIG. 3 is a diagram of a printing system (308) for printing an ammonium-based chalcogenometalate fluid (FIG. 1, 100), according to an example of the principles described herein. The printing system (308) may include a reservoir (310) that supplies the fluid (FIG. 1, 100) to a printhead (326) for deposition onto a substrate (324). In some examples, the fluid is a printable ammonium-based chalcogenometalate fluid (FIG. 1, 100) with the ammonium-based chalcogenometalate precursor (FIG. 1, 102), aqueous solvent (FIG. 1, 104), and water (FIG. 1, 106). For example, the printing system (308) may be an inkjet printing system.

The fluid may pass through a pressure device (320) that serves to regulate the pressure of the fluid as it passes to the reservoir (310). The printing system (308) may include a printhead (326) to carry out at least a part of the functionality of ejecting the printable ammonium-based chalcogenometalate fluid (FIG. 1, 100). The printhead (326) may include a number of components for ejecting the printable ammonium-based chalcogenometalate fluid (FIG. 1, 100). For example, the printhead (326) may include a number of nozzles (312). For simplicity, FIG. 3 indicates a single nozzle (312), however a number of nozzles (312) are present on the printhead (326). A nozzle (312) may include an ejector (314), a firing chamber (316), and an opening (318). The opening (318) may allow fluid to be deposited onto a surface, such as a substrate (324). The firing chamber (316) may include a small amount of fluid. The ejector (314) may be a mechanism for ejecting fluid through the opening (318) from the firing chamber (316), where the ejector (314) may include a firing resistor or other thermal device, a piezoelectric element, or other mechanism for ejecting fluid from the firing chamber (316).

For example, the ejector (314) may be a firing resistor. The firing resistor heats up in response to an applied voltage. As the firing resistor heats up, a portion of the fluid in the firing chamber (316) vaporizes to form a bubble. This bubble pushes liquid fluid out the opening (318) and onto the substrate (324). As the vaporized fluid bubble pops, fluid is drawn into the firing chamber (316) from the reservoir (310), and the process repeats. In this example, the printhead (326) may be a thermal inkjet (TIJ) printhead.

In another example, the ejector (314) may be a piezoelectric device. As a voltage is applied, the piezoelectric device changes shape which generates a pressure pulse in the firing chamber (316) that pushes a fluid out the opening (318) and onto the substrate (324). In this example, the printhead (326) may be a piezoelectric inkjet (PIJ) printhead.

The printhead (326) and printing system (308) may also include other components to carry out various functions related to fluidic ejection. For example, the printing system (308) may include a controller (322) that controls the various components of the printing system (308). For simplicity, in FIG. 3, a number of these components and circuitry included in the printhead (326) and printing system (308) are not indicated; however such components may be present in the printhead (326) and printing system (308).

As described above, the printing system (308) and the ammonium-based chalcogenometalate fluid (FIG. 1, 100) allow for easy deposition of the fluid, and the formation of a solid semiconductive component. Accordingly, any shape, for example a star depicted in FIG. 3, can be reproduced and may form the semiconductive component of an electrical circuit or electronic component.

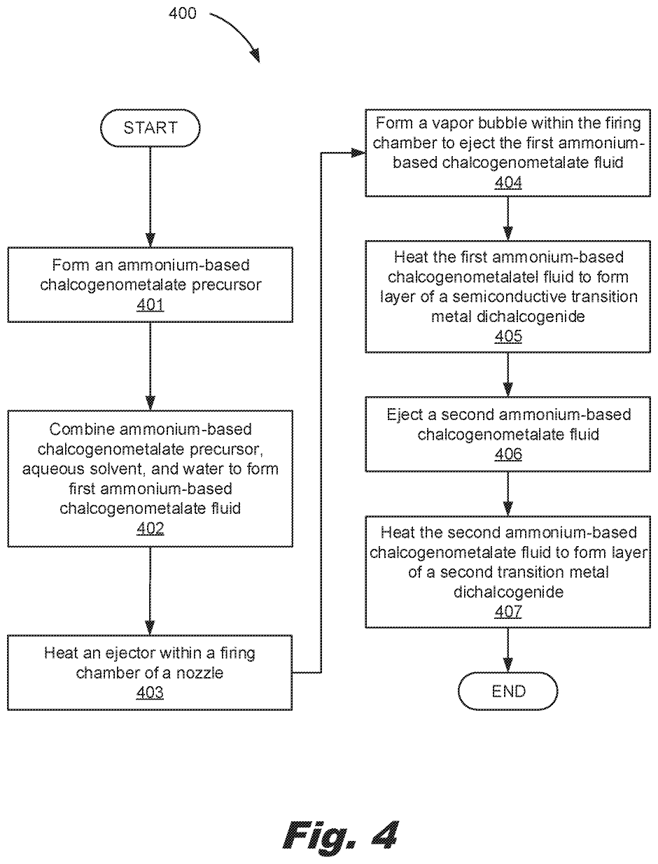

FIG. 4 is a flowchart of a method (400) for printing an ammonium-based chalcogenometalate fluid (FIG. 1, 100), according to an example of the principles described herein. According to the method (400), the ammonium-based chalcogenometalate precursor (FIG. 1, 102) is formed (block 401). Specifically, a compound having the form (NH₄)₂MX₄, where M is a transition metal, and X is a chalcogen selected from the group consisting of sulfur, selenium, tellurium, and oxygen is mixed with a gas.

A specific example of this formation is now provided. In this specific example, an anion solution having the form of (MoO₄)⁻² is put in the presence of ammonia gas resulting in a compound having the form (NH₄)₂MO₄. While this is occurring, a gas such as H₂S, H₂Se, or H₂Te is added and the (NH₄)₂MoS₄ compound forms under a certain temperature and pressure. Once formed, the ammonium-based chalcogenometalate precursor (FIG. 1, 102) is combined (block 402) with the aqueous solvent (FIG. 1, 104) and the water (FIG. 1, 106) to form the first printable ammonium-based chalcogenometalate fluid (FIG. 1, 100). This may be performed as described above in connection with FIG. 2.

The ejector (FIG. 3, 314) within the firing chamber (FIG. 3, 316) of the nozzle (FIG. 3, 312) is then heated (block 403) forming (block 404) a vapor bubble within the firing chamber (FIG. 3, 316). This bubble pushes the printable ammonium-based chalcogenometalate fluid (FIG. 1, 100) out the opening (FIG. 3, 318) and onto the substrate (FIG. 3, 324). As the vaporized fluid bubble pops, fluid is drawn into the firing chamber (FIG. 3, 316) from the reservoir (FIG. 3, 310), and the process repeats. The first ammonium-based chalcogenometalate fluid (FIG. 1, 100) is then heated (block 405) to form a layer of a solid semiconductive transition metal dichalcogenide. This may be performed as described above in connection with FIG. 2.

In some examples, this process may be repeated with a second printable ammonium-based chalcogenometalate fluid (FIG. 1, 100) being ejected (block 406) and heated (block 407) In this fashion, multi-layered structures can simply be formed by printing each layer, rather than by repeating expensive, costly, inefficient, and technically complex chemical vapor deposition processes.

Moreover, in performing multiple CVD processes, it is difficult to make layers that align with previously deposited layers. However, by printing, which is a precise method, the layers can be properly aligned. Moreover, in some examples, the first printable ammonium-based transition metal fluid (FIG. 1, 100) is a different composition than the second printable ammonium-based transition metal fluid (FIG. 1, 100) such that heterogeneous layers can be deposited, in some cases one on top of another, to create different semiconductive properties.

In summary, using such a fluid and method 1) provides manufacturing of 2D semiconductive materials that is cheaper, technically advanced, and more expeditious; 2) expands 2D semiconductor implementation to additional industries not previously available; 3) allows for fabrication of 2D semiconductive materials on substrates that previously were not feasible; 4) provides innumerable options regarding shapes of semiconductive structures; and 5) provides for fully-printable devices such as FETs. However, it is contemplated that the devices disclosed herein may address other matters and deficiencies in a number of technical areas.

The preceding description has been presented to illustrate and describe examples of the principles described. This description is not intended to be exhaustive or to limit these principles to any precise form disclosed. Many modifications and variations are possible in light of the above teaching.

What is claimed is:

1. A printable ammonium-based chalcogenometalate fluid comprising:
an ammonium-based chalcogenometalate precursor;
an aqueous solvent; and
water;
wherein:
the printable ammonium-based chalcogenometalate fluid is printed onto a substrate; and
in the presence of heat, the aqueous solvent, water, and ammonium-based chalcogenometalate precursor dissipate to form a transition metal dichalcogenide having the form MX₂.

2. The fluid of claim 1, wherein the ammonium-based chalcogenometalate precursor has the form (NH₄)₂MX₄ wherein:
M is a transition metal; and
X is a chalcogen.

3. The fluid of claim 1, wherein the ammonium-based chalcogenometalate precursor is selected from the group consisting of:
ammonium tetrathiotungstate; and
ammonium tetrathiomolybdate.

4. The fluid of claim 1, wherein:
the aqueous solvent is selected from the group consisting of:
dimethyl sulfoxide;
dimethylformamide;
N-methyl-2-pyrrolidone; and
1, 2-hexanediol; and
the transition metal dichalcogenide is selected from the group consisting of:
molybdenum disulfide; and
tungsten disulfide.

5. The fluid of claim 1, wherein the transition metal dichalcogenide is transparent.

6. The fluid of claim 1, wherein the aqueous solvent and the water are present in a 2-to-3 ratio.

7. A method comprising:
combining an ammonium-based chalcogenometalate precursor, an aqueous solvent, and water to form a first printable ammonium-based chalcogenometalate fluid;
ejecting, from a nozzle, the first printable ammonium-based chalcogenometalate fluid onto a substrate to form a layer of the first printable ammonium-based chalcogenometalate fluid; and
heating the layer to dissipate the first printable ammonium-based chalcogenometalate fluid into a transition metal dichalcogenide having the form MX₂.

8. The method of claim 7, wherein ejecting, from the nozzle, the first printable ammonium-based chalcogenometalate fluid comprises:
heating an ejector within a firing chamber of the nozzle;
forming a vapor bubble within the firing chamber of the nozzle, which vapor bubble ejects an amount of the printable ammonium-based chalcogenometalate fluid through an opening in the nozzle.

9. The method of claim 7, further comprising:
ejecting, from the nozzle, a second printable ammonium-based chalcogenometalate fluid onto the substrate to form a layer of the second printable ammonium-based chalcogenometalate fluid; and
heating the layer to dissipate the second printable ammonium-based chalcogenometalate fluid into a transition metal dichalcogenide having the form MX₂.

10. The method of claim 9, wherein the second printable ammonium-based chalcogenometalate fluid has a different composition than the first printable ammonium-based chalcogenometalate fluid.

11. The method of claim 7, wherein a composition of the first printable ammonium-based chalcogenometalate fluid is selected based on the substrate on which the first printable ammonium-based chalcogenometalate fluid is to be ejected on.

12. The method of claim 7, wherein the substrate is selected from the group consisting of: graphene, glass, polyethylene terephthalate, aluminum, quartz, sapphire, silicon, silicon dioxide, copper, nickel, ceramics, and gold.

13. The method of claim 7, further comprising:
forming the ammonium-based chalcogenometalate precursor by combining a fluid having the form (NH₄)₂MO_{y} with a gas having the form H₂X where:
M is the transition metal;
Y is a numeric value;
X is a chalcogen selected from the group consisting of:
sulfur;
selenium; and
tellurium.

14. A printing system comprising:
a number of nozzles to eject an amount of printable ammonium-based chalcogenometalate fluid, each nozzle comprising:
a firing chamber to hold the amount of printable ammonium-based chalcogenometalate fluid;
an opening; and
an ejector to eject the amount of printable ammonium-based chalcogenometalate fluid through the opening; and
a reservoir to supply the printable ammonium-based chalcogenometalate fluid to the number of nozzles, the printable ammonium-based chalcogenometalate fluid comprising:
an ammonium-based chalcogenometalate precursor having the form (NH₄)₂MX₄, where:
M is a transition metal; and
X is a chalcogen;
an aqueous solvent; and
water;
wherein in the presence of heat, the printable ammonium-based chalcogenometalate fluid dissipates to form a transition metal dichalcogenide having the form MX₂.

15. The printing system of claim 14, wherein the system is an inkjet printing system.
